(19) United States
(12) Patent Application Publication
(10) Pub. No.: US 2010/0030508 A1
(43) Pub. Date: Feb. 4, 2010

(54) PIN ELECTRONICS CIRCUIT, SEMICONDUCTOR DEVICE TEST EQUIPMENT AND SYSTEM

(75) Inventor: Tatsuhiro Gake, Kanagawa-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/509,575

(22) Filed: Jul. 27, 2009

(30) Foreign Application Priority Data
Jul. 31, 2008 (JP) 2008-198768

(51) Int. Cl. G06F 19/00; G01R 31/26

(52) U.S. Cl. 702/117; 702/124; 702/125; 324/765

(57) ABSTRACT

A main driver and a sub-driver control circuit are provided respectively to receive a test pattern signal for testing a device. The main driver drives the test pattern signal to output a first driven signal. The sub-driver control circuit modifies the test pattern signal to output a modified pattern signal. The modified pattern signal is provided to a sub-driver. The first sub-driver drives the modified pattern signal to output a second driven signal. The first and the second driven signals are combined. The combined signal is provided to a terminal of the device as a test signal.

### CROSS REFERENCE TO RELATED APPLICATION

This application is based upon and claims the benefit of priority from the prior Japanese Patent Application No. 2008-198768, filed on Jul. 31, 2008, the entire contents of which are incorporated herein by reference.

### FIELD OF THE INVENTION

The invention relates to a pin electronics circuit, a semiconductor device test equipment and a semiconductor device test system.

### DESCRIPTION OF THE BACKGROUND

Recently, with miniaturization of a semiconductor deice, operation speed of a semiconductor integrated circuit (LSI) has been higher. In PCT International Publication No. 03/044550 (Page 13, FIG. 9), a semiconductor device test equipment is disclosed, which carries out test of a semiconductor integrated circuit formed in a wafer.

The semiconductor device test equipment mentioned in the above publication causes waveform turbulence such as ringing hardly at an output side of a main driver of the semiconductor integrated circuit, when frequency of a test signal is not high. But, waveform turbulence of a test signal such as ringing may occur at an output terminal of the semiconductor integrated circuit due to influence of a transmission line part such as a probe, when the frequency of the test signal is high.

### SUMMARY OF THE INVENTION

An aspect of the present invention provides a pin electronics circuit, which includes a main driver to receive a test pattern signal for testing a device, the main driver driving the test pattern signal to output a first driven signal, a sub-driver control circuit to receive the test pattern signal, the sub-driver control circuit modifying the test pattern signal to output a modified pattern signal, a first sub-driver to receive the modified pattern signal, the first sub-driver driving the modified pattern signal to output a second driven signal, a signal combination portion to combine the first and second driven signals and to generate a test signal, and an output control circuit to provide the generated test signal to a terminal of the device.

Another aspect of the present invention provides a semiconductor device test equipment, which includes a pattern generator to generate a test pattern, timing data and expected value data, a timing generator to generate a timing signal based on the timing data outputted from the pattern generator, a waveform formatter to combine the test pattern outputted from the pattern generator and the timing signal and to generate a test pattern signal, a digital comparator to receive the expected value data outputted from the pattern generator and the timing signal outputted from the timing generator, a pin electronics circuit, and a judgment unit to evaluate the device according to an output of the digital comparator, wherein the pin electronics circuit receives the test pattern signal outputted from the waveform formatter, the pin electronics circuit provides the test signal to a terminal of a device, and the pin electronics circuit further inputs a test result obtained from the device to the digital comparator to compare with the expected value data.

Further Another aspect of the present invention provides a semiconductor device test system, which includes a semiconductor device test equipment to provide a test signal to a terminal of a device, a waveform observation equipment connected to the terminal of the device to observe a waveform of the test signal at the terminal, and a waveform analyzer to analyze the difference between the expected value data outputted from a pattern generator and waveform information obtained from the waveform observation equipment, the pattern generator being provided in the semiconductor device test equipment.

### BRIEF DESCRIPTION OF THE DRAWINGS

FIG. 1 is a block diagram showing a semiconductor device test equipment according to a first embodiment of the invention.

FIG. 2 is a block diagram showing a structure between a pin electronics circuit and a semiconductor device (object) to be tested.

FIG. 3 is a circuitry diagram showing a pin electronics circuit device used in the first embodiment.

FIG. 4 is a circuitry diagram showing a pin electronics circuit device of a comparative example.

FIG. 5A is a timing chart showing an operation of the pin electronics circuit of FIG. 3.

FIG. 5B is a timing chart showing an operation of the comparative example.

FIG. 6A shows a signal wave of a test signal to be inputted to an I/O terminal of a semiconductor device (object) in the first embodiment.

FIG. 6B shows a signal wave of a test signal to be inputted to an I/O terminal of a semiconductor device (object) in the comparative example.

FIG. 7 is a block diagram showing a semiconductor device test system according to another embodiment of the invention.

FIG. 8 is a circuitry diagram showing main portion of a semiconductor device test equipment according to a second embodiment of the invention.

### DETAILED DESCRIPTION OF THE INVENTION

Hereinafter, embodiments of the invention will be described with reference to the drawings. In the drawings, the same reference numerals designate the same portions, respectively.

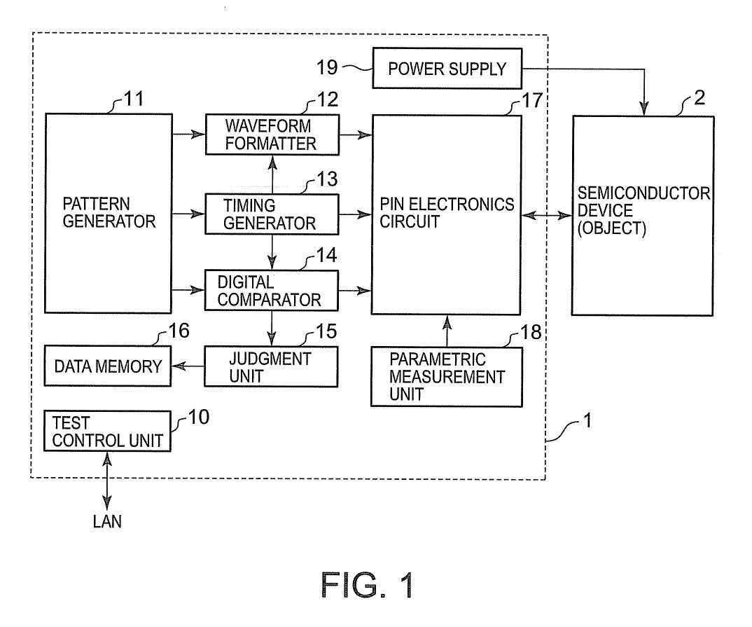

A semiconductor device test equipment according to a first embodiment of the invention will be described. FIG. 1 is a block diagram showing a semiconductor device test equipment according to the first embodiment.

As shown in FIG. 1, a semiconductor device test equipment 1 is provided with a test control unit 10, a pattern generator 11 and a waveform formatter 12. Further, the semiconductor device test equipment 10 is provided with a timing generator 13, a digital comparator 14 and a judgment unit 15. In addition, the semiconductor device test equipment 10 is provided with a data memory 16, a pin electronics circuit 17, a parametric measurement unit 18 and a power provide 19.

The semiconductor device test equipment 1 is an equipment such as a logic tester to carry out test for a device (object) 2 formed in a wafer. The device 2 is a highly integrated LSI or a logic LSI, for example. A system LSI or a SoC (System on a Chip) may be used for the device 2.

The test control unit 10 controls the semiconductor device test equipment 1. The testing control unit 10 is connected to a LAN (Local Area Network). The test control unit 10 downloads information relating to the device 2 or the test related information via the LAN. On the other hand, the test control unit 10 outputs information such as a measurement result information of the device 2 via the LAN.

In the pattern generator 11, a pattern memory, a sequence memory and a sequence controller (respectively not shown) are provided. The pattern generator 11 generates a test pattern, timing data and an expected value based on information stored in the sequence memory.

The timing generator 13 receives the timing data outputted from the pattern generator 11, and generates a timing signal.

The test pattern outputted from the pattern generator 11 and the timing signal outputted from the timing generator 13 are inputted to the waveform formatter 12. The test pattern and the timing signal are combined in the wave formatter 12. A signal generated by the combining is outputted from the waveform formatter 12 as a test pattern signal.

The pin electronics circuit 17, as a signal control circuit, receives the test pattern signal outputted from the waveform formatter 12. The pin electronics circuit 17 drives the received test pattern signal, and outputs a driven test signal. The pin electronics circuit 17 receives a test result signal outputted from an output terminal of the device 2. In FIG. 1, the pin electronics circuit 17 represents one of pin electronics circuits to be provided in the semiconductor device test equipment 1. A concrete construction of the pin electronics circuit 17 will be described later.

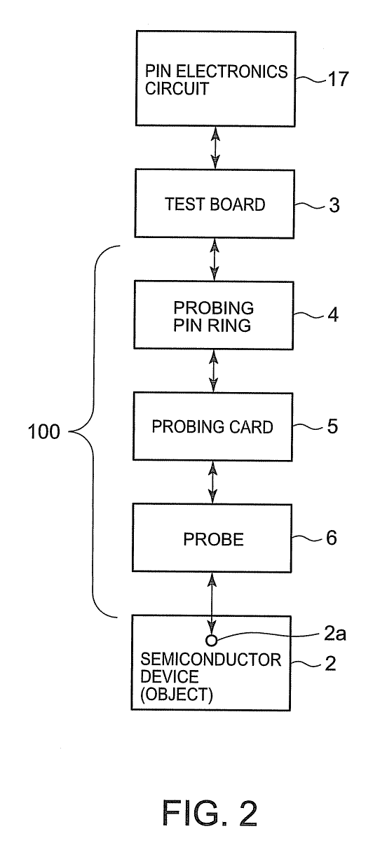

With reference to FIG. 2A, a structure between the pin electronics circuit 17 and the device 2 will be described. As shown in FIG. 2, a test board 3, a probing pin ring 4, a probing card 5 and a probe 6 are provided between the pin electronics circuit 17 and the device 2. The probing pin ring 4, the probing card 5 and the probe 6 are transmission line parts, and constitute a transmission line unit 100.

The test board 3 is provided between the pin electronics circuit 17 and the probing pin ring 4. The test board 3 transmits a test signal outputted from the pin electronics circuit 17 to the probing pin ring 4 side. Reversely, the test board 3 transmits the signal outputted from the probing pin ring 4 to the pin electronics circuit 17 side.

The probing pin ring 4 is provided between the test board 3 and the probing card 5. In FIG. 2, the probing pin ring 4 represents one of a plurality of probing pin rings. The probing pin ring 4 transmits the test signal outputted from the test board 3 to the probing card 5 side via a probe pin.

Reversely, the probing pin ring 4 transmits the signal outputted from the probing card 5 to the test board 3 side via the probe pin.

The probing card 5 is provided between the probing pin ring 4 and the probe 6. The probing card 5 transmits the test signal outputted from the probing pin ring 4 to the probe 6 side.

Reversely, the probing card 5 transmits the signal outputted from the probe 6 to the probing pin ring 4 side.

The probe 6 is provided between the probing card 5 and the device 2. The probe 6 transmits the test signal outputted from the probing card 5 to an I/O terminal 2a of the device 2. Reversely, the probe 6 transmits a test result signal outputted from the I/O terminal 2a of the device 2 to the probing card 5 side.

As the device 2 is a highly integrated LSI, the number of signals or the number of terminals are very large in the device 2 so that pitches among the terminals are narrowed to an extreme. Thus, for testing the device 2, it is difficult to use a coaxial probe which may be matched easily with characteristic impedance. A mono-axial probe is preferably used for the probe 6.

The parametric measurement unit 18 shown in FIG. 1 is connected to the pin electronics circuit 17. The power provide 19 feeds voltage and current necessary for testing the device 2.

The digital comparator 14 shown in FIG. 1 receives the expected value outputted from the pattern generator 11, the timing signal outputted from the timing generator 13 and the signal showing a test result outputted from the pin electronics circuit 17. The digital comparator 14 compares a level of the expected value at the time indicated by the timing signal and the signal level showing a tested result from the pin electronics circuit 17, as a test.

The judgment unit 15 receives the comparison test information outputted from the digital comparator 14. The judgment unit 15 judges whether the comparison test information is good or not.

The data memory 16 stores the judgment information outputted from the judgment unit 15. Simultaneously, the data memory 16 stores address information.

In FIG. 2, the I/O terminal 2a is used to reduce the number of signals or the number of the terminals of the device 2. Instead of the I/O terminal, input and output terminals may be provided separately in a device to be tested. In this case, the construction of the pin electronics circuit 17 needs to be changed as will be described later.

In case that the memory is provided in the device 2, an algorithmic pattern generator (ALPG) is provided in the semiconductor device test equipment 1. In addition, in case that a scan chain is formed in the device 2, a scan pattern generator (SCPG) is provided in the semiconductor device test equipment 1.

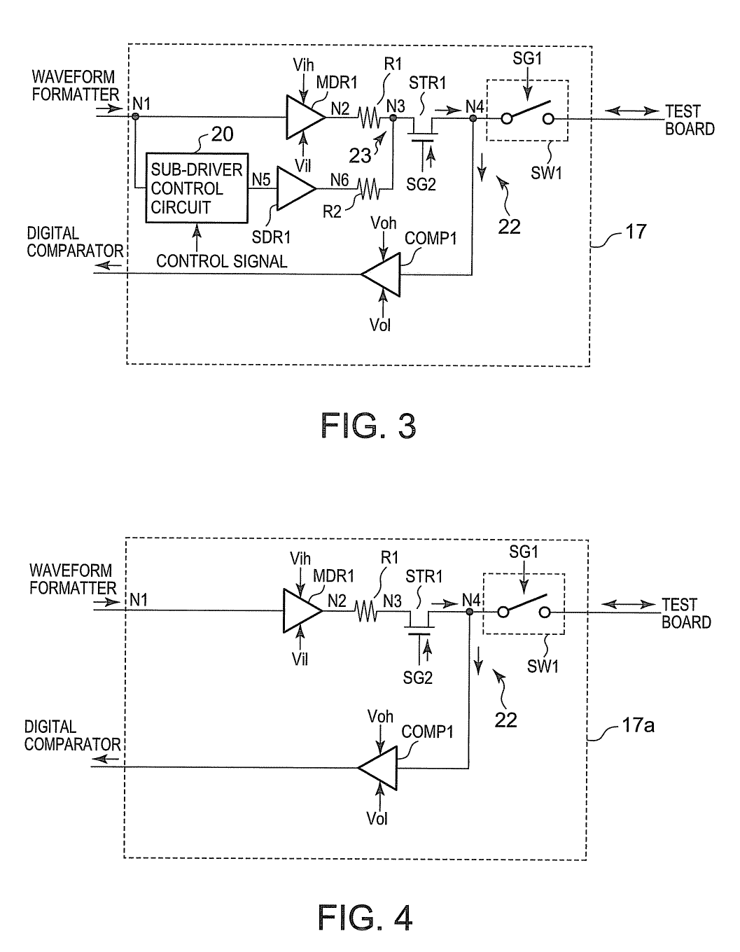

FIG. 3 is a circuit diagram showing a detailed structure of the pin electronics circuit 17 used in the embodiment. As shown in FIG. 3, the pin electronics circuit 17 is provided with a sub-driver control circuit 20, a main driver MDR1 and a sub-driver SDR1. Further, the pin electronics circuit 17 is provided with a comparator COMP1, a control transistor STR1 and a switch SW1. In addition, the pin electronics circuit 17 is provided with a resistor R1 and a resistor R2.

The main driver MDR1 is provided between a node N1 and a node N2. An input voltage Vih of a higher voltage and an input voltage Vil of a lower voltage are respectively applied to the main driver MDR1. The main driver MDR1 receives a test pattern signal outputted from the waveform formatter 12 shown in FIG. 1. The main driver MDR1 drives the received signal and outputs a driven signal. The resistor R1 is provided between the node N2 and a node N3. The signal driven by the main driver MDR1 is inputted to the resistor R1.

The sub-driver control circuit 20 is provided between the node N1 and a node N5. The sub-driver control circuit 20 receives the test pattern signal outputted from the waveform formatter 12.

The sub-driver control circuit 20 carries out modification for the test pattern signal based on a control signal, as described later. The modification may be delaying the test pattern signal, changing the signal level of the test pattern signal or changing the duty ratio of the test pattern signal.

The sub-driver SDR1 is provided between the node N5 and a node N6. The sub-driver SDR1 receives a modified test pattern signal outputted from the sub-driver control circuit 20, The sub-driver SDR1 drives the received signal and outputs a driven signal. The resistor R2 is provided between the node N6 and a node N3. The driven signal is provided to the resistor R2.

The signal driven by the main driver MDR1 and the signal driven by the sub-driver SDR1 are combined at the node N3. The signal obtained by the combining becomes a test signal for the device 2. The node N3 forms a signal combination portion 23.

When the main driver MDR1 and the sub-driver SDR1 are seen from the node N3 side, the resistance of the resistor R1 can be regarded as main driver output resistance. The resistance of the resistor R2 is regarded as sub-driver output resistance. The combined resistance of the two output resistance values is set to approximately the same value as the characteristic impedance of the test signal line which extends from the pin electronics circuit 17 to the device 2 via the transmission line unit 100.

In the case that the resistance value of the resistor R1 as the main driver output resistance is 75Ω, and the resistance value of the resistor R2 as the sub-driver output resistor is 150Ω, for example, the resistance value of the resistors combined at the node N3 is 50Ω, and can be same as an impedance value 50Ω of a test signal line being used ordinarily.

The control transistor STR1 is provided between the node N3 and the node N4. A control signal SG2 is inputted to a gate of the control transistor STR1. When the I/O terminal 2a of the device 2 is in an input state, the control signal SG2 is set in an enable state. Therefore, the control transistor STR1 is turned on, and the test signal is transmitted to the node N4 side.

The switch SW1 is provided between the node N4 and the test board 3 shown in FIG. 2. The test board 3 is connected to the I/O terminal 2a of the device 2 via the probing pin ring 4, the probing card 5 and the probe 6, respectively shown in FIG. 2. The switch SW1 carries out an on/off action based on a control signal SG1. When the device 2 is under testing, the control signal SG1 is set in an enable state. Therefore, the switch SW1 is turned on, and the test signal at the node N4 is transmitted to the I/O terminal 2a of the device 2 via the transmission line unit 100. Reversely, a test result signal of the I/O terminal 2a of the device 2 is transmitted to the node N4 side via the transmission line unit 100. The control transistor STR1 and the switch SW1 forms an output control circuit 22.

The comparator COMP1 is an analog comparator, or an analog/digital converter. The comparator COMP1 is provided between the node N4 and the digital comparator 14. An output voltage Voh of a higher voltage and an output voltage Vol of a lower voltage are respectively applied to the comparator COMP1. The comparator COMP1 receives the test result signal at the node N4. The comparator COMP1 compares the voltage of the test result signal and a predetermined voltage, and converts the test result signal into a digital value of “0” or “1”.

FIG. 4 is a circuit diagram showing a pin electronics circuit 17a according to a comparative example.

As shown in FIG. 4, the pin electronics circuit 17a is provided with the main driver MDR1, the comparator COMP1, the control transistor STR1, the switch SW1 and the resistor R1. The pin electronics circuit 17a is not provided with the sub-driver control circuit 20, the sub-driver SDR1 and the resistor R2 provided in the pin electronics circuit 17 of the embodiment.

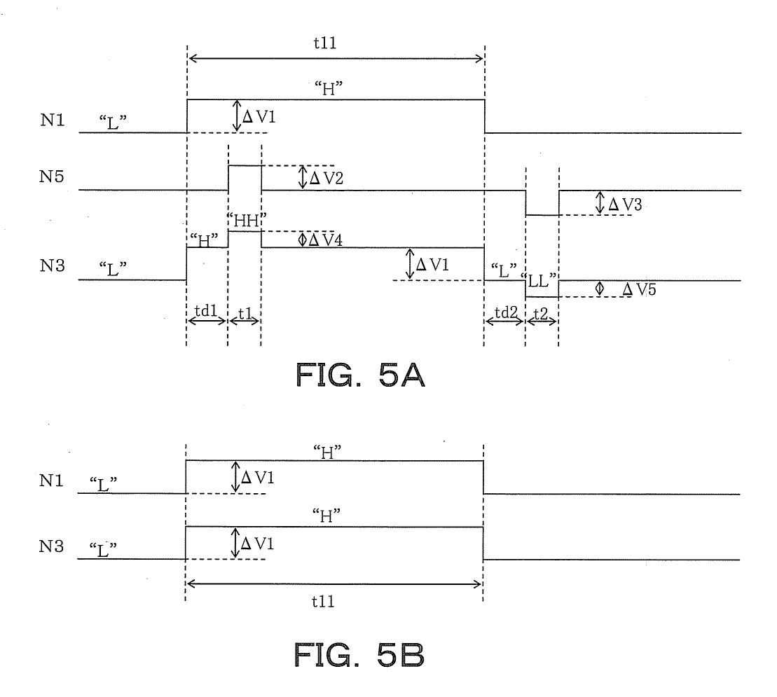

FIG. 5A is a timing chart showing signals respectively generated at the nodes N1, N3 and N5 of the pin electronics circuit of the embodiment. FIG. 5B is a timing chart showing signals respectively generated at the nodes N1 and N3 of the pin electronics circuit of the comparative example.

As shown in FIG. 3, a test pattern signal outputted from the waveform formatter 12 is sent to the node N1 of the pin electronics circuit of the embodiment. The test pattern signal after passing through the node N1 is driven in the main driver MDR1. As shown in FIG. 5A, the test pattern signal has high and low levels. The high level (hereinafter referred to as a “H” level) is larger than the low level (hereinafter referred to as a “L” level) by a potential difference ΔV1, during a time period t11.

On the other hand, the test pattern signal outputted from the waveform formatter 12 is inputted to the sub-driver control circuit 20 via the node N1. The test pattern signal is driven based on a control signal in the sub-driver control circuit 20, and is modified as will be described below. A modified pattern signal is outputted to the node N5 as shown in FIG. 5A.

Through the modification, the rising of the test pattern signal is delayed by a delay time td1, with the sub-driver control circuit 20. Further, the output signal of the sub-driver control circuit 20 has high and low levels, and is set such that the high level is larger than the low level by a potential difference ΔV2. In addition, the duty ratio of the test pattern signal is changed from the period t11 to a period t1 by the sub-driver control circuit 20. The dropping of the test pattern signal is delayed by a delay time td2, and is set to a level lower by a potential difference ΔV3 than the low level of the delayed signal, during the period t2.

The signals driven by the main driver MDR1 and the sub-driver SDR1 are combined at the node N3. The signal obtained at the node N3 is that the “H” level is larger than the “L” level by the potential difference ΔV1 during the delay time td1. The signal obtained at the node N3 indicates a level larger than the “H” level by a potential difference ΔV4 (hereinafter referred to as a “HH” level), during the period t1. Further, the signal obtained at the node N3 is kept at the “H” level, until the signal level becomes at the “L” level after the time period t1. The signal obtained at the node N3 indicates the “L” level during a delayed time td2. The signal obtained at the node N3 shows a level smaller than the “L” level by a potential difference ΔV5 (hereinafter referred to as a “LL” level), during a time period t2. The signal obtained at the node N3 is at the “L” level after the time period t2.

The “HH” level is added to the signal obtained at the node N3 during the time period t1 after the delayed time td1 from the rising edge of the test pattern signal, by the sub-driver control circuit 20. The “LL” level is added to the signal obtained at the node N3 during a time period t2 after the delayed time td2 from the falling edge of the test pattern signal.

On the other hand, in the pin electronics circuit 17a according to the comparative example, the test pattern signal outputted from the waveform formatter 12 is sent to the node N1. As shown in FIG. 5B, the test pattern signal at the node N1 is driven by the main driver MDR1. The signal driven in the main driver MDR1 is outputted to the node N3.

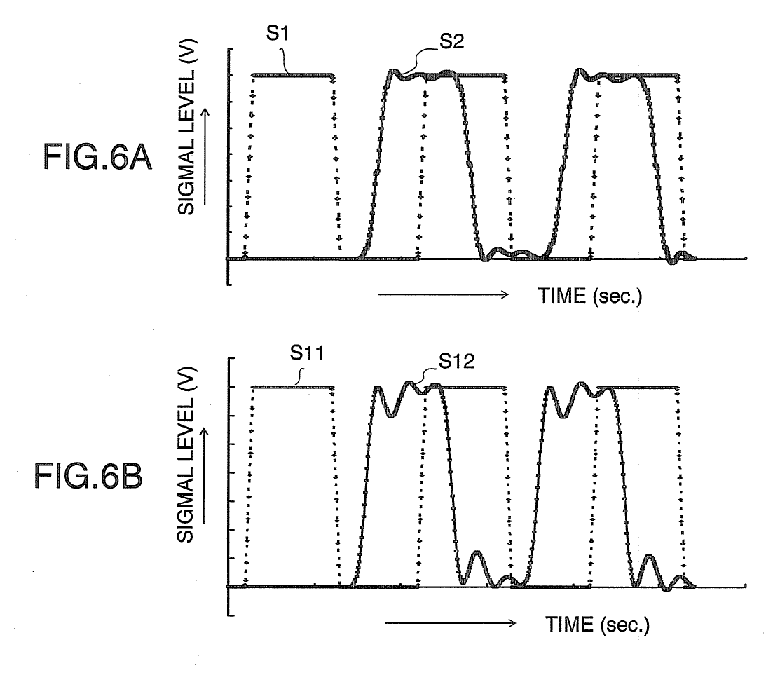

FIG. 6A and FIG. 6B show signal waveforms of test signals being inputted to the I/O terminal 2a of the device 2, respectively, according to the embodiment and according to the comparative example. In FIGS. 6A, 6B, the signals S1, S11 show the signals being obtained at nodes N1 respectively. Signals S2, S12 show the signals being obtained at the I/O terminals 2a respectively.

In the embodiment, as shown in FIG. 3, in addition to the main driver MDR1 and the resistor R1, the sub-driver control circuit 20, the sub-driver SDR1 and the resistor R2 are provided. In the pin electronics circuit 17, the combined resistance value of the resistors R1, R2 is adjusted to become approximately same as the characteristic impedance of the test signal line. As shown in FIG. 5A, the “HH” level (during the time period t1) and the “LL” level (during the time period t2) are added to the signal at the node N3.

As a result, as shown in FIG. 6A, turbulence of the waveform of the signal S2 is small at the I/O terminal 2a of the device 2. Therefore, overshooting and undershooting of the signal are suppressed, and the ringing is reduced.

On the other hand, in the comparative example, as shown in FIG. 4, such units as the sub-driver control circuit 20, the sub-driver SDR1 and the resistor R2, which are provided in the embodiment, are not provided. The test pattern signal outputted from the waveform formatter 12 is only driven by the main driver MDR1, and is provided to the node N3 via the resistor R1.

As a result, as shown in FIG. 6B, turbulence of the waveform of the signal S12 is large at the I/O terminal 2a of the device 2. Therefore, overshooting and undershooting are added to the signal S12, and ringing is possibly generated.

In the embodiment, the turbulence of waveform of a test signal can be made smaller at the I/O terminal 2a of the device 2 so that ringing can be reduced effectively. Thus, the device 2 can be tested with higher accuracy.

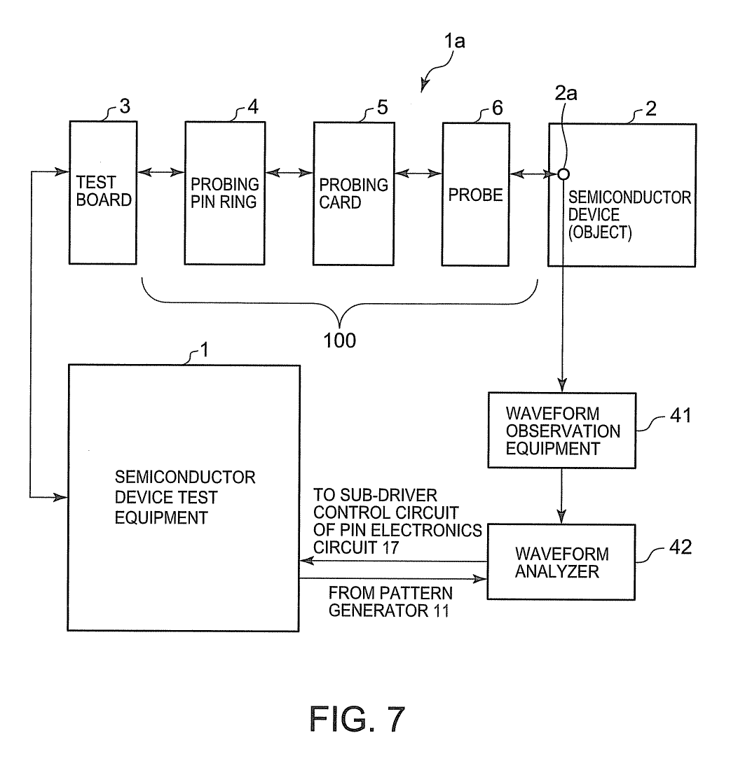

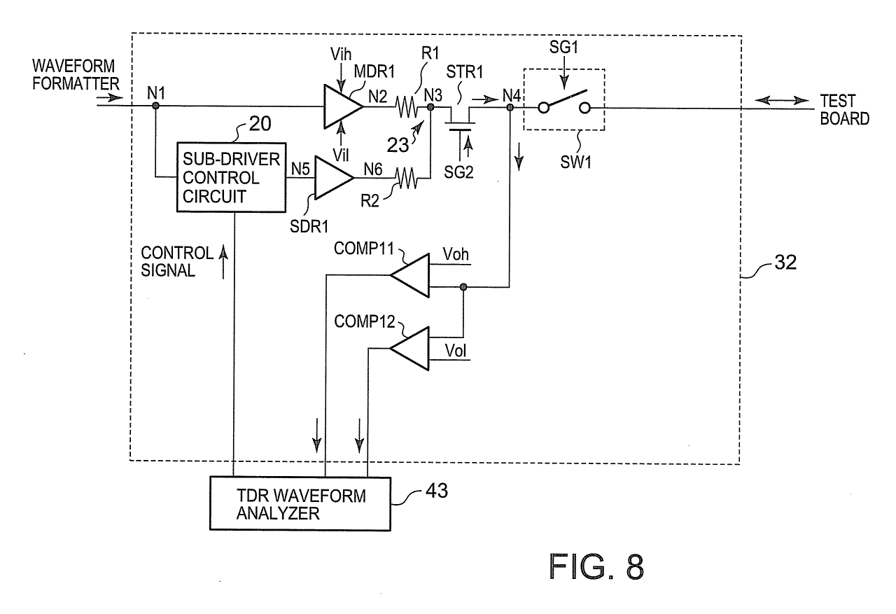

FIG. 7 is a schematic block diagram showing a semiconductor device test system according to another embodiment of the invention.

As shown in FIG. 7, a semiconductor device test system 1a of the embodiment is provided with the semiconductor device test equipment 1 shown in FIG. 1. A test board 3, a probing pin ring 4, a probing card 5 and a probe 6 are provided between an I/O terminal 2a of a device 2 and a pin electronics circuit of the semiconductor device test equipment 1, in the same manner as in the structure shown in FIG. 2.

A waveform observation equipment 41 is connected to the I/O terminal 2a of the device 2. The waveform observation equipment 41 is provided to observe waveform of a signal obtained at the I/O terminal 2a. A waveform analyzer 42 is connected to the waveform observation equipment 41.

The waveform observation equipment 41 is a real time oscilloscope provided with an impedance matched active differential probe, for example. A waveform observation equipment such as a real time spectrum analyzer may be used. The waveform observation equipment 41 observes the waveform of the test signal at the I/O terminal 2a of the device 2 by using the active differential probe.

A noise component is eliminated from a test signal by a trigger processing in advance. The trigger processing makes it possible to show the amount of a contained ringing component more exactly.

The waveform analyzer 42 processes analog waveform information outputted from the waveform observation equipment 41 digitally. The waveform analyzer 42 analyzes the difference between the signal obtained by the digital processing and the test signal based on a expected value outputted from a pattern generator of the pin electronics circuit. The waveform analyzer 42 generates a control signal to modify the test signal at the I/O terminal 2a of the device 2 in accordance with the analyzed difference.

The control signal outputted from the waveform analyzer 42 is inputted to a sub-driver control circuit 20 of the pin electronics circuit.

The sub-driver control circuit modifies the test pattern signal. The modification includes delaying a test pattern signal, changing a signal level of the test pattern signal and changing the duty ratio of the test pattern signal.

The semiconductor device test system according to the embodiment can modify the waveform of the test signal while observing the test signal at the I/O terminal 2a of the device 2. Therefore, the device 2 can be tested more accurately.

FIG. 8 is a circuit diagram showing a main portion of a semiconductor device test equipment according to a second embodiment of the invention.

As shown in FIG. 8, the semiconductor device test equipment according to the embodiment is provided with a pin electronics circuit 32 and a waveform analyzer 43. The waveform analyzer 43 is a TDR (Time Domain Reflectometry) waveform analyzer, for example. The other circuitry units of the semiconductor device test equipment of the third embodiment is same as those shown in FIG. 1.

The pin electronics circuit 32 is provided with a main driver MDR1, a sub-driver SDR1 and a sub-driver control circuit 20, in the same manner as in the pin electronics circuit 17 shown in FIG. 3. Further, the pin electronics circuit 32 is provided with a control transistor STR1, a switch SW1, a resistor R1 and a resistor R2.

Though, the pin electronics circuit 17 shown in FIG. 3 is provided with a single comparator, the pin electronics circuit 32 of the embodiment is provided with two comparators COMP11, COMP12, which are analog comparators. Input terminals of the comparators COMP11, COMP12 are connected to a node N4. Output terminals of the comparators COMP11, COMP12 are connected to the waveform analyzer 43. The other circuitry connections formed in the pin electronics circuit 32 is the same as those of the pin electronics circuit 17 shown in FIG. 3.

The structure between the pin electronics circuit 32 and a device to be tested is same as that shown in FIG. 2.

The sub-driver control circuit 20 of the pin electronics circuit 32 is controlled based on a control signal outputted from the waveform analyzer 43.

When the device is tested, a control signal SG2 is set in an enable state. As a result, the signal generated in the main driver MDR1 is transmitted to the I/O terminal of the device via the control transistor STR1, the switch SW1, the test board and a transmission line unit. The signal obtained from the I/O terminal of the device is transmitted to the comparators COMP11 and COMP12 via the switch SW1.

The comparator COMP11 receives a signal obtained at the node N4. A voltage Voh of a higher voltage inputted to the comparator COMP11. The comparator COMP11 compares the signal obtained at the node N4 with the voltage Voh, and outputs a comparison result.

The comparator COMP12 receives a signal obtained at the node N4. A voltage Vol of a lower voltage is inputted to the comparator COMP11. The comparator COMP12 compares the signal obtained at the node N4 with the voltage Vol, and outputs a comparison result.

The waveform analyzer 43 receives the comparison result signals outputted from the comparator COMP11 and the comparator COMP12. The waveform analyzer 43 analyzes these two signals, and generates a control signal to modify the waveform at the I/O terminal of the device.

The control signal outputted from the waveform analyzer 43 is inputted to the sub-driver control circuit 20 in the pin electronics circuit 32.

As a result, in the sub-driver control circuit 20, modification is carried out for a test pattern signal. The modification includes delaying the test pattern signal, changing a signal level of the test pattern signal and changing the duty ratio of the test pattern signal.

The embodiment may modify the waveform while observing the test signal at the I/O terminal of the device without using the waveform observation equipment shown in FIG. 7. The embodiment makes it possible to test the device 2 more accurately.

In the above-described embodiments, the test signal is transmitted from the pin electronics circuit to the I/O terminal of the device to be tested. The device may be provided with an input terminal and an output terminal separately. In this case, the input terminal is connected to main driver MDR1, the sub-driver SDR1, the sub-driver control circuit 20, the resistor R1, the resistor R2 and the control transistor STR1, which compose the above-described pin electronics circuit. The output terminal is connected to the comparator constituting the pin electronics circuit.

Other embodiments or modifications of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A pin electronics circuit, comprising:
a main driver configured to receive a test pattern signal for testing a device, the main driver driving the test pattern signal to output a first driven signal;
a sub-driver control circuit configured to receive the test pattern signal, the sub-driver control circuit modifying the test pattern signal to output a modified pattern signal;
a first sub-driver configured to receive the modified pattern signal, the first sub-driver driving the modified pattern signal to output a second driven signal;
a signal combination portion configured to combine the first and second driven signals and to generate a test signal; and
an output control circuit configured to provide the generated test signal to a terminal of the device.

2. The pin electronics circuit according to claim 1, wherein the signal combination portion is composed of a first node.

3. The pin electronics circuit according to claim 2, further comprising first and second resistors, wherein
one of the terminals of the first resistor is connected to an output terminal of the main driver, one of the terminals of the second resistor is connected to an output terminal of the sub-driver, and the others of the terminals of the first and the second resistors are connected to the first node.

4. The pin electronics circuit according to claim 1, wherein
the sub-driver control circuit delays the test pattern signal, changes signal level of the test pattern signal, or changes duty ratio of the test pattern signal.

5. The pin electronics circuit according to claim 3, wherein
the output control circuit is composed of a control transistor and a switch connected to each other via a second node, and wherein
one of the terminals of the control transistor is connected to the first node, the other of the terminals of the control transistor is connected to the second node, one of the terminals of the switch is connected to the second node, and the test signal is supplied to the device from the other of the terminals of the switch.

6. The pin electronics circuit according to claim 5, further comprising a first comparator configured to function as an analog/digital converter, wherein an input terminal of the comparator is connected to the second node.

7. The pin electronics circuit according to claim 4, wherein
the sub-driver control circuit sets a time period after a predetermined period following rising of the test pattern signal during which the level of the modified pattern signal is higher than a higher level of the test pattern signal, and sets a time period after a predetermined period following dropping of the test pattern signal during which the level of the modified pattern signal is lower than a lower level of the test pattern signal.

8. A semiconductor device test equipment, comprising:
a pattern generator configured to generate a test pattern, timing data and expected value data;
a timing generator configured to generate a timing signal based on the timing data outputted from the pattern generator;
a waveform formatter configured to combine the test pattern outputted from the pattern generator and the timing signal and to generate a test pattern signal;
a digital comparator configured to receive the expected value data outputted from the pattern generator and the timing signal outputted from the timing generator;
a pin electronics circuit according to claim 1; and
a judgment unit configured to evaluate the device according to an output of the digital comparator;
wherein the pin electronics circuit receives the test pattern signal outputted from the waveform formatter, the pin electronics circuit provides the test signal to a terminal of a device, and the pin electronics circuit further inputs a test result obtained from the device to the digital comparator to compare with the expected value data.

9. The semiconductor device test equipment according to claim 8, wherein the signal combination portion of the pin electronics circuit is composed of a first node.

10. The semiconductor device test equipment according to claim 9, wherein
the pin electronics circuit further includes first and second resistors, and wherein
one of the terminals of the first resistor is connected to an output terminal of the main driver, one of the terminals of the second resistor is connected to an output terminal of the sub-driver, and the others of the terminals of the first and the second resistors are connected to the first node.

11. The semiconductor device test equipment according to claim 8, wherein:
the sub-driver control circuit of the pin electronics circuit delays the test pattern signal, changes signal level of the test pattern signal, or changes duty ratio of the test pattern signal.

12. The semiconductor device test equipment according to claim 10, wherein:
the output control circuit is composed of a control transistor and a switch connected to each other via a second node, and wherein
one of the terminals of the control transistor is connected to the first node, the other of the terminals of the control transistor is connected to the second node, one of the terminals of the switch is connected to the second node, and the test signal is supplied to the device from the other of the terminals of the switch.

13. The semiconductor device test equipment according to claim 12, further comprising:
first and second comparators and a waveform analyzer;
wherein input terminals of the first and the second comparators are connected to the second node, output terminals of the first and the second comparators are connected to the waveform analyzer, and the waveform analyzer outputs the control signal to the sub-driver control circuit of the pin electronics circuit.

14. A semiconductor device test system, comprising:
a semiconductor device test equipment according to claim 8 configured to provide a test signal to a terminal of a device;
a waveform observation equipment connected to the terminal of the device to observe a waveform of the test signal at the terminal; and
a waveform analyzer configured to analyze the difference between the expected value data outputted from a pattern generator and waveform information obtained from the waveform observation equipment, the pattern generator being provided in the semiconductor device test equipment.
